(19) United States
(12) Patent Application Publication
(10) Pub. No.: US 2025/0246437 A1
(43) Pub. Date: Jul. 31, 2025

(54) SELECTIVE ETCHING IN SEMICONDUCTOR DEVICES

(71) Applicant: Tokyo Electron Limited, Tokyo (JP)

(72) Inventors: Adam PRANDA, Albany, NY (US); Yusuke YOSHIDA, Albany, NY (US); Yun HAN, Albany, NY (US)

(73) Assignee: Tokyo Electron Limited, Tokyo (JP)

(21) Appl. No.: 18/424,262

(22) Filed: Jan. 26, 2024

(51) Int. Cl. H01L 21/3213; H01J 37/32; H01L 21/311

(52) U.S. Cl. CPC H01L 21/32136; H01L 21/31116; H01J 37/321; H01J 2237/2065; H01J 2237/3341; H01J 2237/3346; H01J 2237/3348

(57) ABSTRACT

A method includes providing a workpiece in an etching apparatus at ambient temperature, the workpiece comprising a dielectric layer adjacent a conductive layer over a semiconductor substrate. The method includes performing an etching process to selectively remove the dielectric layer relative to the conductive layer. The method further includes, while performing the etching process, cooling the workpiece to a processing temperature that is below the ambient temperature.

### FIELD OF THE DISCLOSURE

This disclosure relates to methods of semiconductor manufacturing and more particularly to selective etching between dielectric materials and conductive materials in semiconductor devices.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device features on a substrate. In recent development, it has become increasingly important to merge and/or compact fabrication steps to reduce processing complexity, cost, and/or time. However, as device features continue to decrease in size, many challenges arise with respect to combining different fabrication steps to achieve specific design goals. For example, emerging semiconductor device fabrication technologies have presented challenges related to selective etching of dielectric materials relative to surrounding conductive or semiconductor materials. While existing methods of performing chemical etching processes have been generally adequate, they are not entirely satisfactory in all aspects.

### SUMMARY

Described herein are methods of implementing etching processes for forming semiconductor devices.

In one aspect, the present disclosure provides a method that includes providing a workpiece in an etching apparatus at ambient temperature, the workpiece comprising a dielectric layer adjacent a conductive layer over a semiconductor substrate. The method includes performing an etching process to selectively remove the dielectric layer relative to the conductive layer. The method further includes, while performing the etching process, cooling the workpiece to a processing temperature that is below the ambient temperature.

In some implementations, performing the etching process includes forming a plasma etchant in the etching apparatus. Performing the etching process further includes applying the plasma etchant to selectively remove the dielectric layer. In some implementations, forming the plasma etchant includes forming an inductively coupled plasma. In some implementations, the processing temperature is greater than or equal to −50° C. and less than 20° C. In some implementations, the processing temperature is greater than or equal to −20° C. and less than or equal to approximately −10° C.

In some implementations, performing the etching process includes ionizing an etchant gas to form a plasma etchant. In some implementations, the method further includes adjusting an ion energy of the plasma etchant. The ion energy is greater than or equal to 150 eV and less than or equal to 200 eV. In some implementations, the present disclosure provides a method that includes cooling the workpiece causes an etching selectivity of the plasma etchant towards the dielectric layer relative to the conductive layer to increase.

In some implementations, the dielectric layer comprises a low-k dielectric material. In some implementations, the conductive layer comprises a metal or a semiconductor material. In some implementations, the conductive layer comprises tungsten.

In another aspect, the present disclosure provides a method that includes providing a sample in an etching apparatus at ambient temperature, where the sample includes a dielectric layer adjacent a conductive layer over a semiconductor substrate. The method includes applying a plasma etchant to the sample in the etching apparatus, where the plasma etchant exhibits a first etching selectivity towards the dielectric layer relative to the conductive layer. The method includes, while applying the plasma etchant, cooling the sample to a processing temperature that is below the ambient temperature, causing the plasma etchant to exhibit a second etching selectivity towards the dielectric layer relative to the conductive layer. The second etching selectivity is greater than the first etching selectivity

In some implementations, the method further includes applying the plasma etchant comprises forming an inductively coupled plasma using an etching gas. In some implementations, the method further includes adjusting an ion energy of the plasma etchant, causing the plasma etchant to exhibit a third etching selectivity towards the dielectric layer relative to the conductive layer. The third etching selectivity is greater than the first etching selectivity.

In some implementations, the processing temperature is greater than or equal to −10° C. and less than 20° C. In some implementations, the dielectric layer is defined by a width and a height, and wherein a ratio of the height to the width is greater than or equal to 15 and less than or equal to 33.3.

In another aspect, the present disclosure provides a method that includes providing a workpiece in an etching apparatus at ambient temperature, where the workpiece includes a dielectric layer adjacent a conductive layer over a semiconductor substrate. The method includes applying a plasma etchant to the workpiece in the etching chamber, the plasma etchant exhibiting a first etching selectivity towards the dielectric layer relative to the conductive layer. The method includes, while applying the plasma etchant, adjusting conditions within the etching apparatus. Adjusting the conditions within the etching apparatus includes cooling the sample to a processing temperature that is below the ambient temperature, causing the plasma etchant to exhibit a second etching selectivity towards the dielectric layer relative to the conductive layer. The second etching selectivity is greater than the first etching selectivity. Adjust the conditions within the etching apparatus further includes adjusting an ion energy of the plasma etchant, causing the plasma etchant to exhibit a third etching selectivity towards the dielectric layer relative to the conductive layer. The third etching selectivity is greater than the first etching selectivity.

In some implementations, applying the plasma etchant includes forming an inductively coupled plasma using a fluorine-containing etching gas. In some implementations, the processing temperature is greater than or equal to −10° C. and less than 20° C.

### BRIEF DESCRIPTION OF THE DRAWINGS

Non-limiting implementations of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIGS. 1 and 2 each illustrate a flowchart of an example method of fabricating a semiconductor structure, in accordance with some implementations.

FIGS. 3, 4, and 5 each illustrate a cross-sectional side view of an example semiconductor structure at intermediate steps of the method illustrated in FIGS. 1 and/or 2, in accordance with some implementations

FIG. 6 illustrates a cross-sectional side view of an example plasma processing apparatus, in accordance with some implementations; and

FIGS. 7, 8, 9A, 9B, 9C, 10A, 10B, and 10C each illustrate a cross-sectional side view of an example semiconductor structure at intermediate steps of the method illustrated in FIGS. 1 and/or 2, in accordance with some implementations.

### DETAILED DESCRIPTION

Reference will now be made to the illustrative implementations depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other implementations may be used or other changes may be made without departing from the spirit or scope of the present disclosure. The illustrative implementations described in the detailed description are not meant to be limiting of the subject matter presented.

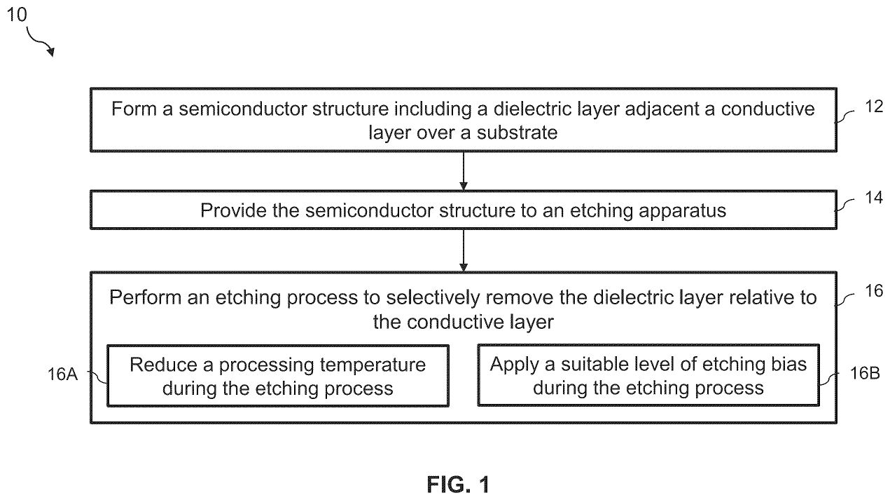

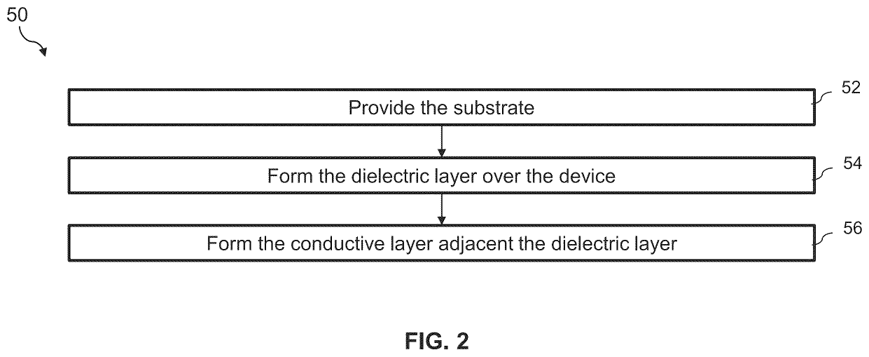

FIG. 1 illustrates a flowchart of an example method 10 for performing a selective etching process to a semiconductor structure, according to some implementations of the present disclosure. FIG. 2 illustrate a flowchart of example method 50, for implementing a portion (e.g., one or more operations) of the method 10, according to some implementations of the present disclosure. It is noted that the methods 10 and 50 are merely examples and are not intended to limit the present disclosure. It is further understood that additional operations may be provided before, during, and after the method 10 of FIG. 1 and the method 50 of FIG. 2, and that some other operations may only be briefly described herein.

In various implementations, operations of the methods 10 and 50 may be associated with an example semiconductor structure 200 at various fabrication stages, which will be discussed in further detail below. It should be understood that the semiconductor structure 200 may include a number of devices such as transistors, resistors, inductors, fuses, capacitors, coils, etc., while remaining within the scope of the present disclosure.

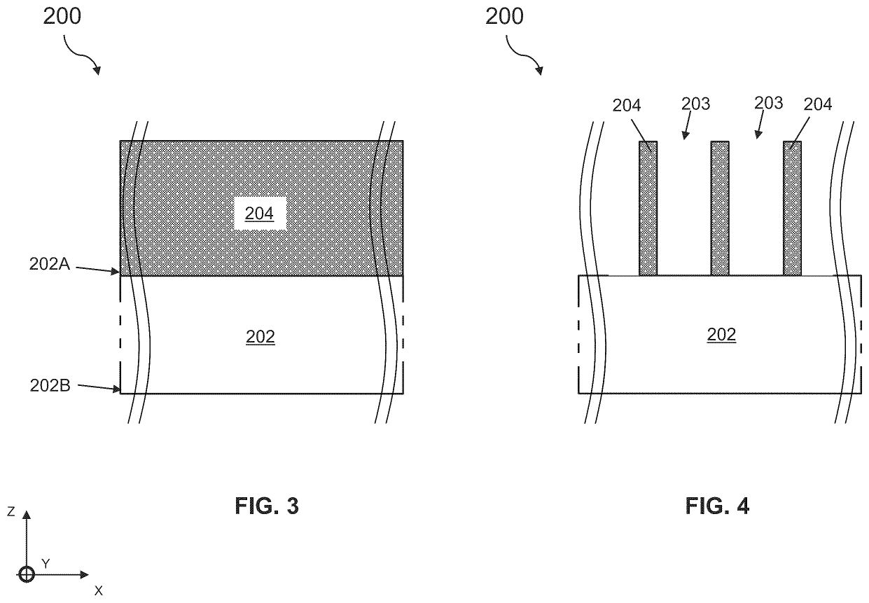

Referring to FIGS. 1-5, the method 10 at operation 12 forms the semiconductor structure 200. The semiconductor structure 200 includes a semiconductor substrate (e.g., a base substrate) 202. The semiconductor structure 200 further includes a dielectric layer 204 and a conductive layer 206 over the semiconductor substrate 202, where the dielectric layer 204 is adjacent the conductive layer 206 along a lateral direction, such as the X axis as depicted in FIG. 3.

In some implementations, the operation 12 is implemented by the method 50 of FIG. 2. For example, referring to FIGS. 2 and 3, the method 50 at operation 52 provides the semiconductor substrate 202, where the semiconductor substrate 202 may include one or more device features (not depicted) formed therein and/or thereover. The semiconductor substrate 202 includes a semiconductor material, such as a bulk semiconductor, a semiconductor-on-insulator (SOI), or the like, which may be doped (e.g., with a p-type or an n-type dopant) or undoped. The semiconductor substrate 202 may be or correspond to a wafer, such as a silicon wafer. Generally, an SOI includes a layer of a semiconductor material formed on an insulator layer. The insulator layer may be, for example, a buried oxide (BOX) layer, a silicon oxide layer, or the like. The semiconductor substrate 202 may include other semiconductor materials, such as a multi-layered or gradient semiconductor material. In some examples, the semiconductor substrate 202 may include silicon, and/or germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP.

The device features may include any suitable active or inactive device features, such as transistors, diodes, resistors, etc, formed in and/or over the semiconductor substrate 202. Non-limiting example transistors include field-effect transistors (FETs) such as fin-like FET (e.g., FinFET), multi-gate FETs, nanosheet FETs, the like, or combinations thereof. An example transistor may include a gate structure (e.g., a metal gate structure) traversing a channel region defined in and/or over the semiconductor substrate 202 and interposed between a pair of source/drain features. The example transistor may be formed in and/or over the semiconductor substrate 202 via a series of fabrication processes, such as patterning, implantation, deposition, planarization, etc. The device features may be formed as a part of a front-end-of-line (FEOL) processing. In some implementations, a surface of the semiconductor substrate 202 over which the device features are formed is defined as a frontside 202A of the semiconductor substrate 202, which also includes a backside 202B opposite the frontside 202A.

Though not depicted for purposes of simplicity, the semiconductor substrate 202 may further include contact features and interconnect features operatively (e.g., electrically and/or physically) coupled to the device features. The contact features may each be coupled to a gate structure, a source/drain feature, or the like. The interconnect features may include horizontal interconnect features (e.g., conductive lines) and vertical interconnect features (e.g., vias). The contact features and the interconnect features may each be formed in a suitable dielectric layer (e.g., similar to the dielectric layer 204 in composition) via a series of patterning and deposition processes (e.g., single- or dual-damascene processes). In some implementations, the dielectric layer 204 and the conductive layer 206 constitute a portion of an interconnect feature. The contact features and the interconnect features may be formed as a part of a middle-end-of-line (MEOL) processing and back-end-of-line (BEOL) process, respectively.

Subsequently, still referring to FIGS. 2 and 3, the method 50 at operation 54 forms the dielectric layer 204 (or the insulating layer) on or overlaying the semiconductor substrate 202. The dielectric layer 204 may include any suitable material containing an oxide, a nitride, a carbide, the like, or combinations thereof. In some implementations, the dielectric layer 204 includes a low-k dielectric material having a dielectric constant less than that of silicon oxide, which is about 3.9. In some implementations, the low-k dielectric material includes a nitride (or is nitrogen-containing). In some implementations, the low-k dielectric material includes silicon nitride (SiN) doped with one or more non-metal elements, such as carbon, oxygen, boron, the like, or combinations thereof. For example, the low-k dielectric material may include silicon carbonitride (SiCN), silicon oxycarbonitride (SiOCN), silicoboron carbonitride (SiBCN), the like, or combinations thereof. The dielectric layer 204 may be formed or deposited using at least one suitable deposition technique, such as chemical vapor deposition (CVD), flowable CVD (FCVD), atomic layer deposition (ALD), spin coating, the like, or combinations thereof.

Referring to FIGS. 2, 4, and 5, the method 10 at operation 56 forms the conductive layer 206 (or the conductive feature) adjacent the dielectric layer 204, where the conductive layer 206 may be configured to interconnect with one or more underlying conductive features (e.g., metallization layers, interconnect structures, device features, etc.). The conductive layer 206 may include any suitable conductive material, such as tungsten, copper, nickle, aluminum, ruthenium, silver, gold, platinum, titanium, tantalum, the like, or combinations thereof. In the depicted implementations, the conductive layer 206 includes tungsten. In some implementations, the conductive layer 206 includes a semiconductor material, such as an epitaxially grown silicon-containing material.

In some implementations, referring to FIG. 4, forming the conductive layer 206 includes forming recesses 203 in the dielectric layer 204 by performing a patterning process. For example, a patterned mask layer (not depicted) may be formed over the dielectric layer 204 using a suitable lithography technique, where the patterned mask layer is formed with one or more openings corresponding to positions of the recesses 203, and the dielectric layer 204 may be etched or patterned using the patterned mask layer as an etch mask, resulting in the recesses 203 in the dielectric layer 204. The patterned mask layer is subsequently removed from the semiconductor structure 200.

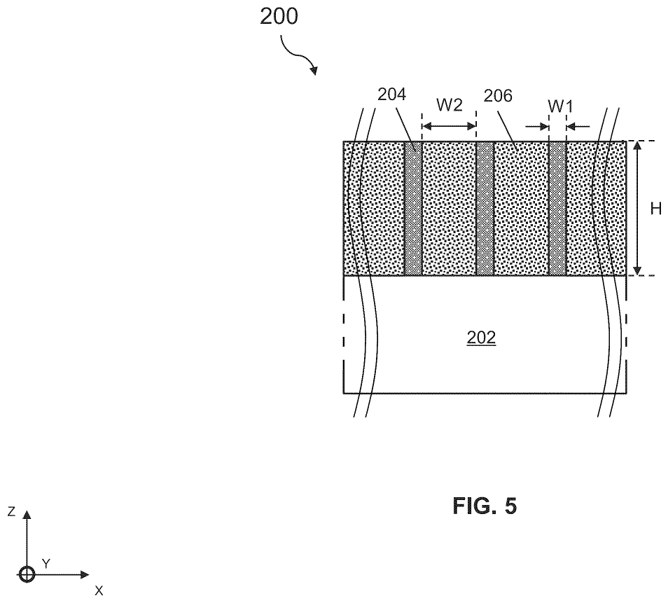

Subsequently, referring to FIG. 5, the conductive layer 206 is deposited as a blanket layer over the semiconductor structure 200 to fill the recesses 203 and overlay the top surface of the dielectric layer 204. The conductive layer 206 may be deposited by any suitable deposition technique, such as CVD, ALD, PVD, plating (e.g., electroplating, electroless plating, etc.), the like, or combinations thereof. The blanket layer and any underlying layers may then be etched (e.g., by a dry etching, a reactive ion etching (RIE), or a wet etching process) or polished (e.g., by a chemical-mechanical polishing/planarization, or CMP, process) until the top surface of the dielectric layer 204 is exposed, thereby forming the conductive layer 206 adjacent the dielectric layer 204. Additional features may be formed over the dielectric layer 204 and the conductive layer 206 to complete fabrication of the semiconductor structure 200.

In some implementations, still referring to FIG. 5, the dielectric layer 204 is formed to a width W1 extending laterally (e.g., along the X axis) and a height H extending vertically (e.g., along the Z axis), where a ratio of the height H to the width W1 defines an aspect ratio AR1 of the dielectric layer 204. As depicted herein, the ART of the dielectric layer 204 is greater than the aspect ratio AR2 of the conductive layer 206, which is defined as a ratio of the height H to a width W2 that is greater than the width W1. In some non-limiting examples, the width W1 may be greater than or equalt to approximately 6 nm and less than or equal to approximately 10 nm, and the height H may be greater than or equal to approximately 150 nm and less than or equal to approximately 200 nme, rendering the aspect ratio AR1 of the dielectric layer 204 to be greater than or equal to approximately 15 and less than or equal to approximately 33.3.

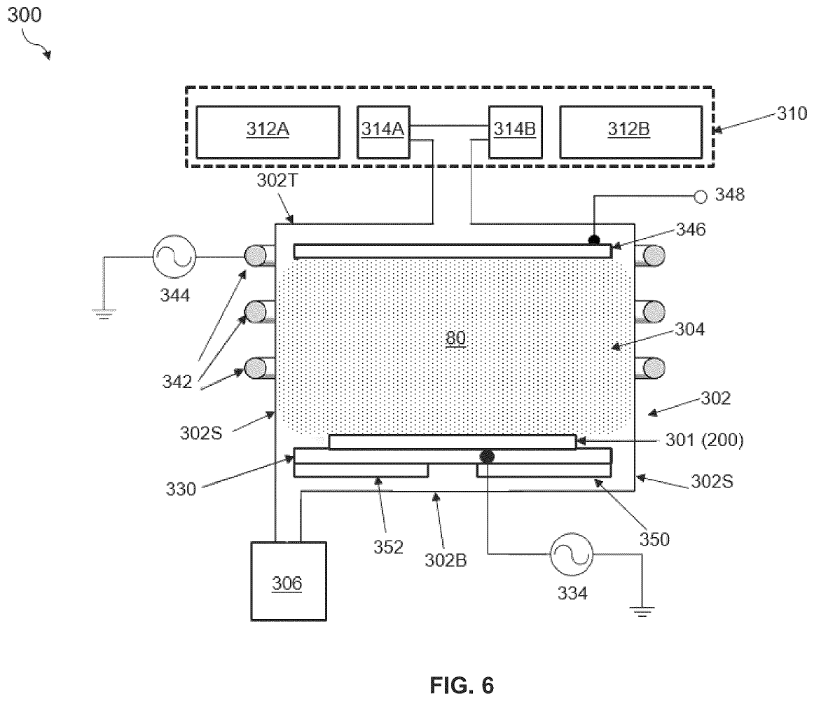

Referring to FIGS. 1, and 6, after forming the dielectric layer 204 and the conductive layer 206, the method 10 at operation 14 provides the semiconductor structure 200 to a plasma processing apparatus 300, an example of which is depicted in FIG. 6.

The plasma processing apparatus 300 includes a processing chamber 302 configured to house a workpiece 301 (or a wafer, a substrate, etc.) and facilitate the processing (e.g., etching) of the workpiece 301 using a plasma source 80, for example. In the depicted embodiment, the workpiece 301 includes the semiconductor structure 200 formed thereon. The processing chamber 302 includes a top end wall 302T, a bottom end wall 302B opposite the top end wall 302T, and sidewalls 302S vertically interposed between the top end wall 302T and the bottom end wall 302B. The top end wall 302T, the bottom end wall 302B, and the sidewalls 302S together define a cavity 304 within the processing chamber 302. In the present implementations, the plasma processing apparatus 300 is configured to perform an etching process to the workpiece 301 and is therefore alternatively referred to as an etching apparatus 300.

The plasma processing apparatus 300 includes a gas supply system 310 fluidly coupled to the processing chamber 302 and configured to delivery one or more gase sources to the cavity 304. In some implementations, the gas supply system 310 is fluidly coupled to the top end wall 302T. The gas supply system 310 includes one or more gas sources, such as gas sources 312A and 312B, each fluidly coupled to a valve 314A and 314B, respectively. The valves 314A an 314B are configured to regulate pressure of gases supplied by their respective gas sources. In some implementations, the gas sources 312A and 312B are each configured to provide an etching gas, a protective gas, a delivery gas, an inert gas, the like, or combinations thereof, to the cavity 304 through the valves 314A and 314B, respectively.

In some implementations, the plasma processing apparatus 300 includes a gas outlet 306 fluid coupled to the processing chamber 302 at a location removed from the gas supply system 310, such as to the bottom end wall 302B in the depicted implementation. The gas outlet 306 may be configured to remove any excess gases from the cavity 304. In some embodiments, the excess gases are removed by a pump (e.g., a mechanical pump, a diffusion pump, etc.) through the gas outlet 306.

The plasma processing apparatus 300 includes a sample support 330 for holding the workpiece 301 thereon. The sample support 330 includes an electrically conductive material and is configured to be coupled to a power source, such as an radio frequency (RF) source 334. The sample support 330 may be alternatively referred to as an electrostatic chuck. In some implementations, the sample support 330 includes a thermally conductive material. In the present implementations, the workpiece 301 is operatively coupled or fastened to a top side (e.g., proximal to the top end wall 302T) of the sample support 330 by any suitable means. For example, in the depicted implementation, the workpiece 301 is placed on the top side of the sample support 330 with the semiconductor structure 200 facing upward, i.e., facing the gas supply system 310.

The plasma processing apparatus 300 further includes components configured to generate the plasma source 80 in the cavity 304 from the gas(es) provided by the gas supply system 310. In some implementations, the plasma source 80 includes an inductively coupled plasma (ICP) generated by a set of conductive coils 342 coupled to an exterior surface of the sidewalls 302S of the processing chamber 302. The conductive coils 342 are powered by an RF source 344 to ionize the gases provided by the gas supply system 310. For implementations in which the plasma source 80 is configured to etch portions of the semiconductor structure 200, the RF source 344 may be adjusted to produce the plasma source 80 having a desired ion density (or flux).

Additionally, the ionization by the RF source 344 may also provide a bias voltage (or etching bias) relative to the RF source 334, which is grounded under ICP conditions, causing ions of the plasma source 80 to accelerate towards the workpiece 301. In some implementations, increasing the bias voltage increases an ion energy of the plasma source 80, resulting in a more anisotropic (or vertically directional) etching profile. Conversely, decreasing the bias voltage decreases the ion energy of the plasma source 80, resulting in a more isotropic (or less anisotropic) etching profile.

The plasma processing apparatus 300 further includes components configured to adjust a temperature (or processing temperature) of the sample support 330, which consequently affects a temperature (or processing temperature) of the workpiece 301 while it remains within the cavity 304. In the present implementations, the plasma processing apparatus 300 includes a chiller 350 operatively coupled to a portion of the sample support 330. For example, as depicted herein, the chiller 350 is operatively coupled to a bottom side (e.g., proximal to the bottom end wall 302B) of the sample support 330. Although the chiller 350 is depicted to be in direct contact with the bottom side of the sample support 330, the present disclosure is not limited as such. In some implementations, the chiller 350 is set at a fixed temperature that is significantly lower than a temperature of the sample support 330. In some implementations, the chiller 350 cools the workpiece 301 by any suitable means, such as by performing a heat exchange process with a circulating fluid. In an example implementation, the chiller 350 is set at approximately −70° C.

The plasma processing apparatus 300 may further include a thermal modulator 352 configured to heat the sample support 330 such that, when coupled with the operation of the chiller 350, the temperature of sample support 330 can be modulated more precisely to achieve a desired degree. Similar to the chiller 350, the thermal modulator 352 may be operatively coupled to a portion of the sample support 330, such as at the bottom side of the sample support 330 proximal to the bottom end wall 302B. Although the thermal modulator 352 is depicted to be in direct contact with the bottom side of the sample support 330, the present disclosure is not limited as such. In some implementations, the thermal modulator 352 heats the sample support 330 by any suitable means, such as by resistive heating, or the like.

In various implementations, the temperature of the workpiece 301 is modulated by the chiller 350 and the thermal modulator 352 in the presence of the plasma source 80 during an etching process performed within the plasma processing apparatus 300, for example. In some implementations, both the chiller 350 and the thermal modulator 352 are disabled, such that the workpiece 301 is processed at ambient temperature (or room temperature), defined herein to be greater than or equal to approximately 18° C. and less than or equal to approximately 22° C., such as at approximately 20° C.

In some implementations, the plasma processing apparatus 300 further includes a top electrode 346 coupled to a power source 348. By applying a bias voltage between the top electrode 346 and the sample support 330, the plasma processing apparatus 300 can be configured to produce a conductively coupled plasma (CCP) in addition to the ICP produced by the conductive coils 342.

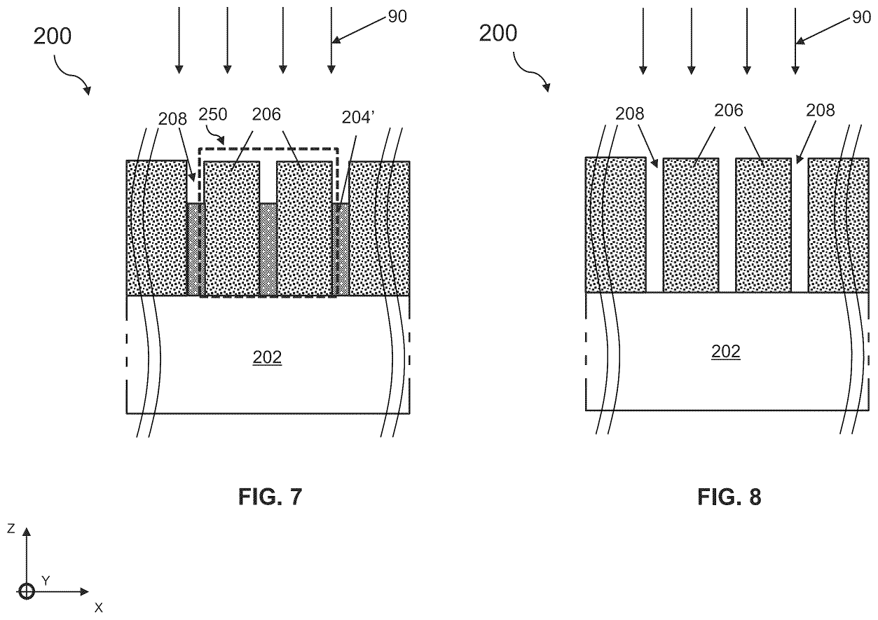

Referring now to FIGS. 1 and 7, the method 10 at operation 16 performs an etching process 90 to the workpiece 301 in the plasma processing apparatus 300 (or an implementation thereof) by applying the plasma source 80. The etching process 90 is configured to selectively remove portions of the dielectric layer 204 without removing, or substantially removing, portions of the conductive layer 206, resulting in a recessed dielectric layer 204′ in a recess 208 (or trench). In other words, the etching process 90 is configured to selectively etch the dielectric layer 204 relative to the conductive layer 206.

In the present implementations, the etching process 90 is performed using the plasma source 80 described herein, where the plasma source 80 (or plasma etchant) includes an ICP, which is formed by ionizing an etching gas. To achieve selective etching, the etching gas has a composition configured to chemically react with the dielectric layer 204 (including a low-k dielectric material) while remaining inactive, or substantially inactive, towards the conductive layer 206 (including a metal or a semiconductor material) during the etching process 90. In some implementations, the etching gas includes a fluorine-containing gas with a chemical formula CₓH_{y}F_{z}, where x≥1, y≥0, and z≥0, where values of x, y, and z satisfy stoichiometric ratios suitable for a given chemical formula. In some implementations, y may be greater than z. In some implementations, y may be less than z. In some implementations, y is 0, such that the etching gas may have a chemical formula CₓF_{z}. In some implementations, the etching gas further includes a protective gas, an inner gas, a delivery gas, the like, or combinations thereof. For example, the etching gas may include O₂, CO₂, CO, H₂, Ar, the like, or combinations thereof. Other compositions of etching gas may also be applicable to the present implementations, depending on the compositions of the dielectric layer 204 and the conductive layer 206. In one example implementation, where the dielectric layer 204 includes a nitrogen-containing low-k dielectric material, such as SiCN, SiBCN, and/or SiOCN, and the conductive layer 206 includes tungsten, the plasma source 80 includes ionized CH₃F and O₂, which may be provided by the gas sources 312A and 312B, respectively.

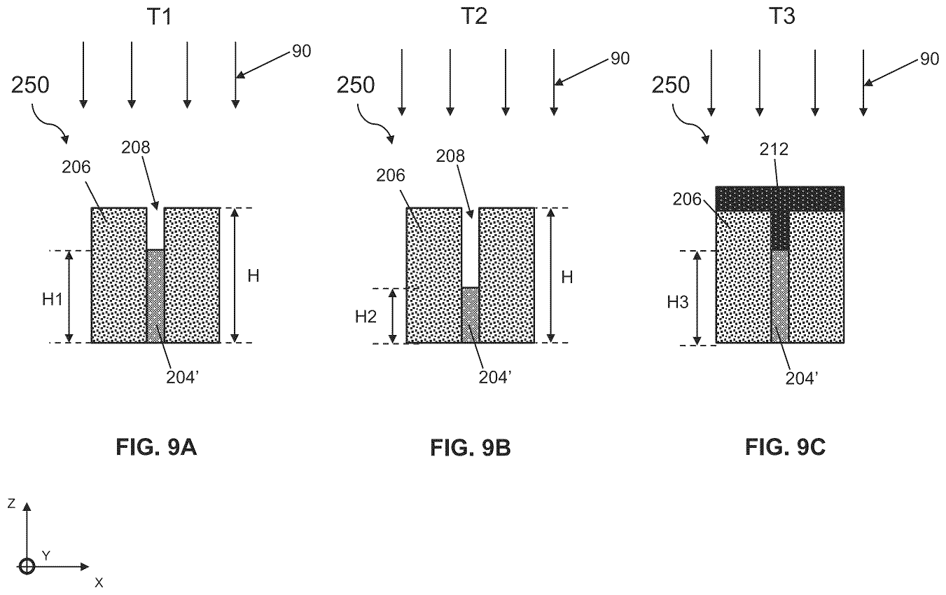

In some implementations, the processing temperature of the semiconductor structure 200 (i.e., the workpiece 301), the ion energy of plasma source 80, or a combination thereof, may be adjusted to alter the etching selectivity of the dielectric layer 204 relative to the conductive layer 206. For example, referring to FIGS. 9A-9C, which each depict a portion 250 of the semiconductor structure 200 within a dashed enclosure of FIG. 7, an effect of different processing temperatures of the semiconductor structure 200 (i.e., the workpiece 301) on the etching selectivity of the plasma source 80 applied during the etching process 90 is illustrated. Specifically, FIG. 9A illustrates the semiconductor structure 200 (including the portion 250) subject to a first processing temperature T1 that is similar to the ambient temperature defined herein. An etching selectivity S1 of the plasma source 80 towards the dielectric layer 204 relative to the conductive layer 206 at the first processing temperature T1 may correspond to (or be estimated) as a ratio of the height H of the conductive layer 206 to a height H1 of the recessed dielectric layer 204′. In some implementations, the first processing temperature T1 is achieved without utilizing the chiller 350 or the thermal modulator 352 in the plasma processing apparatus 300.

In contrast, referring to FIG. 9B, the semiconductor structure 200 may be subject to a second processing temperature T2 that is less than the ambient temperature. With all other conditions of the etching process 90 held constant, the recessed dielectric layer 204′ formed at the second processing temperature T2 has a height H2 that is less than the height H1, indicating that an etching selectivity S2 (corresponding to a ratio of H/H2) of the plasma source 80 towards the dielectric layer 204 relative to the conductive layer 206 at the second processing temperature sT2 is greater than the etching selectivity S1 (corresponding to the ratio of H/H1).

In some implementations, the etching selectivity of the plasma source 80 towards the dielectric layer 204 relative to the conductive layer 206 progressively increases as the processing temperature decreases from approximately 40° C. to approximately −20° C. Processing temperatures outside this range result in either reduced etching of the dielectric layer 204 or a buildup of etching byproducts as depicted in FIG. 9C. For instances, the second processing temperature T2 capable of causing the etching selectivity (i.e., S2) to increase relative to the etching selectivity observed at the ambient temperature (i.e., S1) is greater than or equal to approximately −20° C. and less than approximately 20° C. In some examples, the second processing temperature T2 may be greater than or equal to approximately −20° C. and less than approximately 20° C. In some examples, the second processing temperature T2 may be greater than or equal to approximately −20° C. and less than or equal to approximately 0° C.

Furthermore, referring to FIG. 9C, the semiconductor structure 200 may be subject to a third processing temperature T3. With all other conditions of the etching process 90 held constant, the recessed dielectric layer 204′ formed at the third processing temperature T3 has a height H3 that is greater than the height H₂, indicating that an etching selectivity S3 (corresponding to a ratio of H/H3) of the plasma source 80 towards the dielectric layer 204 at the third processing temperature T3 is less than the etching selectivity S2. In some implementations, the third processing temperature T3 is outside the range of approximately −20° C. to approximately 40° C. As such, the third processing temperature T3 may be at or greater than the ambient temperature or less than the second processing temperature T2.

In some implementations, the reduction in the etching selectivity at the third processing temperature T3 is attributed to the formation of a blocking layer 212 on the recessed dielectric layer 204′ during the etching process 90, which may inhibit further removal of the dielectric layer 204. The blocking layer 212 may include an etching byproduct of the dielectric layer 204. For a fluorine-containing gas with a chemical formula CₓH_{y}F_{z} defined above, the blocking layer 212 may include a fluorocarbon-containing polymer that is formed from the dissociation of the fluorine-containing gas in the plasma that is then deposited on surfaces of the semiconductor structure to form a polymer. Some portions of the blocking layer 212 may also be formed on the conductive layer 206.

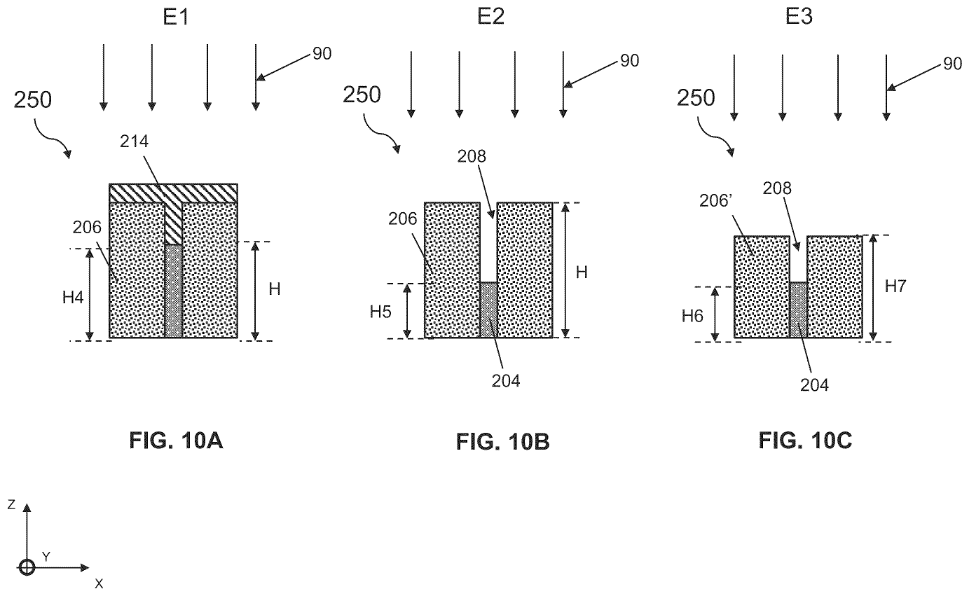

Referring to FIGS. 10A-10C, which each depict the portion 250, an effect of different levels of ion energy on the etching selectivity of the plasma source 80 towards the dielectric layer 104 is illustrated. Specifically, FIG. 10A illustrates the semiconductor structure 200 subject to a first ion energy E1, where an etching selectivity S4 of the plasma source 80 towards the dielectric layer 204 relative to the conductive layer 206 may correspond to (or be estimated as) a ratio of the height H of the conductive layer 206 to a height H4 of the recessed dielectric layer 204′. In some implementations, the chemical reaction between the plasma source 80 and the dielectric layer 204 forms a fluorocarbon-containing byproduct (e.g., polymer) that is subsequently re-deposited in the recesses 208 over the recessed dielectric layer 204′, thereby inhibiting further removal of the dielectric layer 204.

In contrast, referring to FIG. 10B, the semiconductor structure 200 may be subject to a second ion energy E2 that is greater than the first ion energy E1. With all other conditions of the etching process 90 held constant, the recessed dielectric layer 204′ formed at the second ion energy E2 has a height H5 that is less than the height H4, indicating that an etching selectivity S5 (corresponding to a ratio of H/H5) of the plasma source 80 towards the dielectric layer 204 relative to the conductive layer 206 at the second ion energy E2 is greater than the etching selectivity S4 (corresponding to the ratio of H/H4). In some implementations, the ion energy E2 is greater than or equal to approximately 150 eV and less than or equal to approximately 200 eV. In some implementations, specific ranges of the second ion energy E2 is positively correlated with the aspect ratio (AR) of the recess 203 (i.e., the dielectric layer 204), where a higher AR indicates a higher ion energy is needed to achieve a desired degree of etching selectivity with all other etching conditions (including the processing temperature) held constant.

Furthermore, referring to FIG. 10C, the semiconductor structure 200 may be subject to a third ion energy E3 that is greater than the second ion energy E2. With all other conditions of the etching process 90 held constant, the recessed dielectric layer 204′ formed at the third ion energy E3 has a height H6. Due to increased ion bombardment at the elevated third ion energy E3, the conductive layer 206 is also inadvertently etched to form a recessed conductive layer 206′ having a height H7. As depicted herein, the height H6 may be similar to the height H5 and the height H7 may be less than the height H, indicating that an etching selectivity S6 (corresponding to a ratio of H7/H6) of the plasma source 80 towards the dielectric layer 204 at the third ion energy E3 is less than the etching selectivity S5.

Accordingly, when a suitable processing temperature that is less than the ambient temperature (e.g., the second processing temperature T2) is applied during the etching process 90, the etching selectivity (e.g., the etching selectivity S2) of the plasma source 80 towards the dielectric layer 204 relative to the conductive layer 206 is improved when compared to processing temperatures that are at or greater than the ambient temperature (e.g., the first processing temperature T1 and the third processing temperature T3). Furthermore, when a suitable amount of etching bias is applied to result in a suitable level of ion energy during the etching process 90, the etching selectivity (e.g., the etching selectivity S5) of the plasma source 80 towards the dielectric layer 204 relative to the conductive layer 206 is improved when compared to ion energies that are less than such a suitable processing temperature (e.g., the first ion energy E1) or greater than such a suitable processing temperature (e.g., the third ion energy E3).

In this regard, referring to FIG. 1, performing the etching process 90 at the operation 16 includes simultaneously performing operation 16A by reducing the processing temperature (i.e., cooling the semiconductor structure 200) within the etching apparatus 300 and operation 16B by applying a suitable level of etching bias to improve the etching selectivity of the plasma source 80 towards dielectric layer 204 relative to the conductive layer 206. In the present implementations, the processing temperature is reduced to below the ambient temperature as described herein, while the etching bias is adjusted with respect to the aspect ratio of the dielectric layer 204 (i.e., the recess 208).

In some implementations, referring to FIG. 8, the etching process 90 is continued until the dielectric layer 204 is completely removed from the semiconductor structure 200. In this regard, the recesses 208, now air gaps between portions of the conductive layer 206, are configured as low-k dielectric features with reduced parasitic capacitance in comparison to the dielectric layer 204, contributing to improved electrical performance for the semiconductor structure 200.

With increased etching selectivity arising from a lowered processing temperature and a higher ion energy during the plasma-based (e.g., ICP-based) etching process 90, inadvertent damage to the conductive features (e.g., the conductive layer 206) may be reduced or minimized. In addition, dielectric features (e.g., the dielectric layer 204) with higher aspect ratios may be more effectively etched to form defined air gaps (e.g., recesses 208) exhibiting improved insulating properties for the adjacent conductive features.

In the preceding description, specific details have been set forth, such as a particular geometry of a processing system and descriptions of various components and processes used therein. It should be understood, however, that techniques herein may be practiced in other implementations that depart from these specific details, and that such details are for purposes of explanation and not limitation. Implementations disclosed herein have been described with reference to the accompanying drawings. Similarly, for purposes of explanation, specific numbers, materials, and configurations have been set forth in order to provide a thorough understanding. Nevertheless, implementations may be practiced without such specific details. Components having substantially the same functional constructions are denoted by like reference characters, and thus any redundant descriptions may be omitted.

Various techniques have been described as multiple discrete operations to assist in understanding the various implementations. The order of description should not be construed as to imply that these operations are necessarily order dependent. Indeed, these operations need not be performed in the order of presentation. Operations described may be performed in a different order than the described implementation. Various additional operations may be performed and/or described operations may be omitted in additional implementations.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of implementations of the invention are not intended to be limiting. Rather, any limitations to implementations of the invention are presented in the following claims.

What is claimed is:

1. A method, comprising:
providing a workpiece in an etching apparatus at ambient temperature, the workpiece comprising a dielectric layer adjacent a conductive layer over a semiconductor substrate;
performing an etching process to selectively remove the dielectric layer relative to the conductive layer; and
while performing the etching process, cooling the workpiece to a processing temperature that is below the ambient temperature.

2. The method of claim 1, wherein performing the etching process comprises:
forming a plasma etchant in the etching apparatus; and
applying the plasma etchant to selectively remove the dielectric layer.

3. The method of claim 2, wherein forming the plasma etchant comprises ionizing a fluorine-containing gas.

4. The method of claim 2, wherein forming the plasma etchant comprises forming an inductively coupled plasma.

5. The method of claim 1, wherein the processing temperature is greater than or equal to −50° C. and less than 20° C.

6. The method of claim 5, wherein the processing temperature is greater than or equal to −20° C. and less than or equal to approximately −10° C.

7. The method of claim 1, wherein performing the etching process comprises ionizing an etchant gas to form a plasma etchant.

8. The method of claim 7, further comprising adjusting an ion energy of the plasma etchant, wherein the ion energy is greater than or equal to 150 eV and less than or equal to 200 eV.

9. The method of claim 7, wherein cooling the workpiece causes an etching selectivity of the plasma etchant towards the dielectric layer relative to the conductive layer to increase.

10. The method of claim 1, wherein the dielectric layer comprises a low-k dielectric material.

11. The method of claim 1, wherein the conductive layer comprises a metal or a semiconductor material.

12. The method of claim 11, wherein the conductive layer comprises tungsten.

13. A method, comprising:
providing a sample in an etching apparatus at ambient temperature, the sample comprising a dielectric layer adjacent a conductive layer over a semiconductor substrate;
applying a plasma etchant to the sample in the etching apparatus, the plasma etchant exhibiting a first etching selectivity towards the dielectric layer relative to the conductive layer; and
while applying the plasma etchant, cooling the sample to a processing temperature that is below the ambient temperature, causing the plasma etchant to exhibit a second etching selectivity towards the dielectric layer relative to the conductive layer, the second etching selectivity being greater than the first etching selectivity.

14. The method of claim 13, wherein applying the plasma etchant comprises forming an inductively coupled plasma using an etching gas.

15. The method of claim 13, further comprising adjusting an ion energy of the plasma etchant, causing the plasma etchant to exhibit a third etching selectivity towards the dielectric layer relative to the conductive layer, the third etching selectivity being greater than the first etching selectivity.

16. The method of claim 13, wherein the processing temperature is greater than or equal to −10° C. and less than 20° C.

17. The method of claim 13, wherein the dielectric layer is defined by a width and a height, and wherein a ratio of the height to the width is greater than or equal to 15 and less than or equal to 33.3.

18. A method, comprising:
providing a workpiece in an etching apparatus at ambient temperature, the workpiece comprising a dielectric layer adjacent a conductive layer over a semiconductor substrate;
applying a plasma etchant to the workpiece in the etching apparatus, the plasma etchant exhibiting a first etching selectivity towards the dielectric layer relative to the conductive layer; and
while applying the plasma etchant, adjusting conditions within the etching apparatus, wherein the adjusting comprises:
cooling the workpiece to a processing temperature that is below the ambient temperature, causing the plasma etchant to exhibit a second etching selectivity towards the dielectric layer relative to the conductive layer, the second etching selectivity being greater than the first etching selectivity, and
adjusting an ion energy of the plasma etchant, causing the plasma etchant to exhibit a third etching selectivity towards the dielectric layer relative to the conductive layer, the third etching selectivity being greater than the first etching selectivity.

19. The method of claim 18, applying the plasma etchant comprises forming an inductively coupled plasma using a fluorine-containing etching gas.

20. The method of claim 18, wherein the processing temperature is greater than or equal to −10° C. and less than 20° C.
